(19) United States
(12) Patent Application Publication
(10) Pub. No.: US 2016/0240701 A1
(43) Pub. Date: Aug. 18, 2016

(54) SOLAR CELL MODULE WITH ANTIFOULING LAYER

(71) Applicant: E I DU PONT DE NEMOURS AND COMPANY, Wilmington, DE (US)

(72) Inventor: Xu HAN, Shanghai (CN)

(73) Assignee: E I DU PONT DE NEMOURS AND COMPANY, Wilmington, DE (US)

(21) Appl. No.: 14/873,560

(22) Filed: Oct. 2, 2015

(30) Foreign Application Priority Data
Oct. 8, 2014 (CN) 201410520907.0

(51) Int. Cl. H01L 31/0216; H01L 31/048

(52) U.S. Cl. CPC H01L 31/02167; H01L 31/0488

(57) ABSTRACT

The invention relates to a solar cell module with an antifouling layer, which comprises: (i) a solar cell layer, including a solar cell part and having a front side and a rear side, and the solar cell part being formed by one or more solar cells, and (ii) a front panel positioned at the front side of the solar cell layer, wherein the front panel is formed by a transparent substrate and an antifouling layer positioned at the front side of the transparent substrate, wherein the antifouling layer comprises at least one trivalent fluorine-containing silane fragment in the following formula:

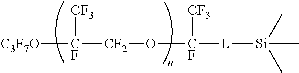

Wherein, n is an integer between 7-40, L is a bivalent organic group selected from —CH₂OCH₂CH₂CH₂— and —C(O)NHCH₂CH₂CH₂—, and the at least one trivalent fluorine-containing silane fragment and the transparent substrate are subject to covalent bonding.

### FIELD OF THE INVENTION

The invention relates to a solar cell module with an anti-fouling layer.

### BACKGROUND OF THE INVENTION

In order to meet the ever-increasing requirement of energy consumption, development of solar energy has drawn widespread attention. People adopt various methods to convert solar energy into electric energy. At present, the most mature design for achieving this aim is use of a solar cell module.

Quantity of light transmitting through a transparent front panel (such as a transparent glass panel) in the solar cell module is a key factor influencing the efficiency of the solar cell module. However, in a natural environment, accumulation of dust particles on the front panel of the solar cell module severely obstructs the transmission of incident light, so power-generating efficiency of the solar cell module is reduced. Sometimes, due to the influence of one storm, the power-generating efficiency of the solar cell module is reduced by 10-30%. A large amount of rainwater runoff is a natural force capable of effectively removing the dust particles. However, in the Gobi or desert regions, the rainwater resource is very limited. Besides, after being mixed, a small quantity of rainwater or dew and dust very easily form limescale. Places with the limescale residue are very hard to clean, and afterwards, more dust is accumulated in these regions. Due to dust obstruction on part of the front panel of the solar cell module, a hot spot phenomenon forms, and this process accelerates aging of the solar cell, and even causes fires. Therefore, a technique needs to be developed, for example, an antifouling layer is prepared on the external surface of the front panel of the solar cell module so as to reduce the accumulation of dust and improve the problem of antifouling of the front panel of the solar cell module, and furthermore, to avoid both reduced power-generating efficiency of the solar cell module due to dust accumulation as well as the hot spot phenomenon.

### SUMMARY OF THE INVENTION

The invention provides a solar cell module, which comprises (i) a solar cell layer, including a solar cell part and having a front side and a rear side, and the solar cell part being formed by one or more solar cells, and (ii) a front panel positioned at the front side of the solar cell layer, wherein the front panel is formed by a transparent substrate and an antifouling layer positioned at the front side of the transparent substrate, wherein the antifouling layer comprises at least one trivalent fluorine-containing silane fragment in the following formula:

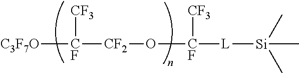

Wherein, n is an integer between 7 and 40, L is a bivalent organic group selected from —CH₂OCH₂CH₂CH₂— and —C(O)NHCH₂CH₂CH₂—, and the at least one trivalent fluorine-containing silane and the transparent substrate are subject to covalent bonding. In one embodiment, L is —CH₂OCH₂CH₂CH₂—.

In another embodiment of the solar cell module, the transparent substrate is glass.

In another embodiment of the solar cell module, the antifouling layer is formed by coating a coating composition with the trivalent fluorine-containing silane in the following formula: C₃F₇O(CF(CF₃)CF₂O)ₙCF(CF₃)-L-Si(OR)₃ to the front side of the transparent substrate, wherein n is an integer between 7-40, L is a bivalent organic group selected from —CH₂OCH₂CH₂CH₂— and —C(O)NHCH₂CH₂CH₂—, and R is respectively independently selected from methyl, ethyl, propyl or isopropyl.

In another embodiment of the solar cell module, the antifouling layer is prepared by the following method: (a) providing a coating composition, which comprises at least one trivalent fluorine-containing silane, at least one solution, and at least one of any catalyst; (b) coating the coating composition to the front side of the transparent substrate; and (c) drying and curing the transparent substrate coated with the coating composition.

In another embodiment of the solar cell module, the at least one solvent contains a fluorine-containing solvent with a normal boiling point being 50-150° C.

In another embodiment of the solar cell module, the at least one solvent is selected from hydrofluorocarbon, hydrofluorocarbon saturated ether, unsaturated fluorocarbon ether and a mixture thereof. In another embodiment, the at least one solvent is saturated hydrofluorocarbon.

In another embodiment of the solar cell module, the at least one solvent is a fluorine-free solvent, the fluorine-free solvent is selected from alcohol, ketone, nitrile, cyclic ether, non-cyclin ether, and a mixture thereof, and the normal boiling point of the fluorine-free solvent is 50-150° C. In another embodiment, the at least one solvent is selected from methyl alcohol, ethyl alcohol, propyl alcohol, isopropyl alcohol, acetone, methyl ethyl ketone, acetonitrile, tetrahydrofuran and a mixture thereof.

### BRIEF DESCRIPTION OF THE DRAWINGS

FIG. 1 is an image of a front side of an antifouling-coating-free solar cell module which is subject to an antifouling test and prepared in CE1;

FIG. 2 is an image of a front side of an antifouling-coating-containing solar cell module, which is subject to an antifouling test and prepared in E1;

### DETAILED DESCRIPTION OF EMBODIMENTS

Unless otherwise explained, all publications, patent applications, patents, and other references put forward in the text are all clearly cited into the text with their full content, as though all of them were completely disclosed in the text.

Unless otherwise defined, all scientific terms used in the text have the same meaning generally understood by those of common skill in the art of the invention. When a conflict occurs, definition in the disclosure is taken as a standard.

Unless otherwise explained, all percentages, parts, and proportions are calculated by weight.

In the text, the term “prepared by . . . ” is equal to “containing”. The terms: “comprising”, “containing”, “having”, “possessing” “including” or other any variants used in the text intend to cover non-exclusive comprising. For example, compositions, processes, methods, products, or equipment comprising a series of key factors are not limited to those key factors, and can further contain key factors which are not definitely listed or other inherent key factors of those compositions, processes, methods, products, or equipment.

The conjunction “formed/consisting of . . . ” does not contain any indefinitely listed key factors, steps or components. If occurring in claims, the conjunction enables the claims to be limited to described materials without containing non-described materials, but to still contain impurities generally related to the described materials. When the conjunction “formed/consisting of . . . ” appears in characteristic parts of the claims instead of being close to preorder parts, the conjunction is only limited to the key factors elaborated in the characteristic parts; other key factors are not excluded from the whole claims.

The conjunction “basically formed/consisting of . . . ” is used for defining that the compositions, methods or equipment also contain additional materials, steps, characteristics, components or key factors besides those literal materials, steps, characteristics, components, or key factors described under the premise that those additional materials, steps, characteristics, components, or key factors do not substantively affect basic characteristics and novel characteristics of the to-be-protected invention. The term “basically formed/consisting of . . . ” is in the middle region between the “containing/including” and “formed/consisting of . . . ”.

The term “containing/comprising” intends to comprise embodiments covered by the terms “basically formed/consisting of . . . ” and “formed/consisting of . . . ” Similarly, the term “basically formed/consisting of . . . ” intends to comprise the embodiments covered by the term “formed/consisting of . . . . ”

When quantity, concentration, or other values or parameters are given according to a range, a preferable range or a series of upper limit preferable values or lower limit preferable values, it should be understood that all ranges formed by any pair of values of any larger range limiting values or preferable values and any smaller range limiting values or preferable values are specifically disclosed no matter the ranges are respectively disclosed or not. For example, when the range of “1-5” is described, the described ranges should comprise “1-4”, “1-3”, “1-2”, “1-2 and 4-5”, “1-3 and 3-5” and the like. Unless otherwise explained, at the range of values described in the text, the ranges intend to comprise range end values and all integers and fractions in the ranges.

When term “about” is used for describing the values or end values of the ranges, it should be understood that the disclosed content contains specific values or end values.

In addition, unless definitely expressing an opposite meaning, “or (either)” means inclusive “or (either)” instead of non-exclusive “or (either)”. For example, any following conditions are suitable for condition “A or B”: A is true (or existing) and B is false (or not existing), A is false (or no existing) and B is true (or existing), and A and B are both true (or existing).

Unless specifically explained, the materials, methods and examples described in the text are schematic instead of limiting. Although methods and materials similar or equal to those methods and materials described in the text can be used for the implementation or test of the invention, proper methods and materials are still described in the text.

The invention is described in detail as follows:

A solar cell means any product which can convert solar energy into electric energy. Examples of various types of solar cells comprise, for example, a single crystalline silicon solar cell, a multicrystalline silicon solar cell, a microcrystalline silicon solar cell, an amorphous silicon-based solar cell, a copper indium diselenide solar cell, a polymer semiconductor solar cell, a dye-sensitive solar cell and the like. The most commonly seen types of solar cells comprise the multicrystalline silicon solar cell, a thin film solar cell, the polymer semiconductor solar cell and the amorphous silicon-based solar cell.

In actual application, the solar cell is packaged and coated by a packaging and protection material and forms a solar cell module so as to be suitable for use in an outside natural environment.

The invention provides a solar cell module with an antifouling layer, which comprises: (i) a solar cell layer including a solar cell part and having a front side and a rear side, the solar cell part consisting of one or more solar cells, and (ii) a front panel positioned at the front side of the solar cell layer, wherein the front panel is formed by a transparent substrate and an antifouling layer positioned at the front side of the transparent substrate. The solar cell part comprises one or more solar cells, and preferably, the multiple solar cells are electrically interconnected or arranged in one plane. In addition, the solar cell layer can further contain a power wiring, such as a halved belt or bus.

In the text, the solar cell layer is generally provided with a front light receiving side (also called as “front side” and generally facing the sun under an actual use condition) and a back non-light receiving side (also called as a “back side” and generally back to the sun under the actual use condition). In addition, in actual use, all modules in the solar cell module are provided with front sides facing a light source (e.g., the sun) and back sides back to the light source (e.g., the sun). In the solar cell module, all materials positioned at the front light-receiving side of the solar cell layer should have transparency allowing sufficient sunlight to reach the solar cells, for example, the average transmittance is larger than or equal to 70% under the wavelength of 400-1100 nm (measured by a spectrophotometer such as UVNIS/NiR, wherein, incident light is vertical to the surface of an object to be measured). The material of the non-light receiving side at the back of the solar cells does not have to be transparent.

In the text, the transparent substrate can be selected from any proper sheets or films. A proper sheet can be a glass sheet or a plastic sheet such as polycarbonate, acrylic resin, polyacrylate, cyclic polyolefin (for example, ethylene/norbornene polymer), polystyrene (preferably, metallocene-catalyzed polystyrene), polyamide, polyester, fluorine polymers or combination of two or more. A proper film can comprise, but is not limited to, the following polymers: polyester (for example, polyethylene glycol terephthalate and polyethylene naphthalate), polycarbonate, polyolefin (for example, polypropylene, polyethylene and cyclic polyolefin), polystyrene (for example, syndiotatic polystyrene), styrene-acrylate copolymer, acrylonitrile-styrol copolymer, polyamide, polyurethane, acrylic resin, cellophane, polyvinyl chloride (for example, polyvinylidene chloride), fluorine polymers (for example, polyvinyl fluoride, polyvinylidene fluoride, polytetrafluoroethylene, ethylene-tetrafluoroethylene copolymer and the like) and a combination of two or more.

In the text, the transparent substrate is preferably glass sheet; the term “glass” not only comprises window glass, panel glass, silicate glass, sheet glass, low sodium glass, tempered glass, CeO-free tempered glass, and floating glass, but also comprises colored glass, special glass (for example, special glass containing components for controlling solar energy to heat), coated glass (for example, coated glass sputtered by metals such as silver or indium tin oxide with the aim of controlling solar energy), E-glass, Toroglass, Solex™ glass (US PPG Industries) and Starphire™ glass (PPG Industries). Those special glasses are disclosed in US patents, such as U.S. Pat. Nos. 4,615,989; 5,173,212; 5,264,286; 6,150,028; 6,340,646; 6,461,736; and 6,468,934. Those skilled in the art select glass types for specific modules according to expected purposes.

In the text, the antifouling layer positioned at the front side of the transparent substrate comprises at least one trivalent fluorine-containing silane fragment in the following formula:

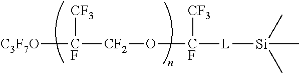

Wherein n is an integer between 7-40, L is a bivalent organic group selected from —CH₂OCH₂CH₂CH₂— and —C(O)NHCH₂CH₂CH₂—, and the trivalent fluorine-containing silane fragment and the transparent substrate in the front panel of the solar cell module are subject to covalent bonding.

The antifouling layer disclosed by the invention is formed by coating at least one coating composition with the trivalent fluorine-containing silane in the following formula:

C₃F₇O(CF(CF₃)CF₂O)ₙCF(CF₃)-L-Si(OR)₃ to the front side of the transparent substrate, wherein n is an integer between 7-40, L is a bivalent organic group selected from —CH₂OCH₂CH₂CH₂— and —C(O)NHCH₂CH₂CH₂—, and R is respectively independently selected from methyl, ethyl, propyl or isopropyl.

The coating composition comprises at least one trivalent fluorine-containing silane in the following formula: C₃F₇O(CF(CF₃)CF₂O)ₙCF(CF3)-L-Si(OR)₃, and can further comprise at least one solvent and at least one of any catalyst.

The trivalent fluorine-containing silane in the following formula: C₃F₇O(CF(CF₃)CF₂O)ₙCF(CF₃)-L-Si(OR)₃ can be prepared by known methods in the art. For example, C₃F₇O(CF(CF₃)CF₂O)ₙCF(CF₃)CH₂OCH₂CH₂CH₂Si(OCH₃)₃ can be prepared by performing hydrosilation reaction on C₃F₇O(CF(CF₃)CF₂O)ₙCF(CF₃)CH₂OH. As a further example, C₃F₇O(CF(CF₃)CF₂O)ₙCF(CF₃)C(O)NHCH₂CH₂CH₂Si(OCH₃)₃ can be prepared by reaction of C₃F₇O(CF(CF₃)CF₂O)ₙCF(CF₃)C(O)OCH₃ and NH₂CH₂CH₂CH₂Si(OCH₃)₃. The content of the trivalent fluorine-containing silane in the following formula: C₃F₇O(CF(CF₃)CF₂O)ₙCF(CF₃)-L-Si(OR)₃ is about 0.1% to 2.0% of weight of the total weight of the coating composition.

Wherein the at least one solvent can be fluorine-containing solvent or fluorine-free solvent. The fluorine-containing solvent can be selected from hydro fluorocarbon, hydrofluorocarbon saturated ester, unsaturated fluorocarbon ether and a mixture thereof, and preferably, saturated hydrofluorocarbon. The proper fluorine-containing solvent comprises: methoxy nonafluoro butane, ethoxy nonafluoro butane, perfluorohexane and 2H, 3H-decafluoropentane. The fluorine-containing solvent suitable for the invention can be purchased, for example the methoxy nonafluoro butane with a trademark of HFE7100 purchased from 3M Company of US, or the 2H, 3H-decafluoropentane with a trade mark of Vertrel® XF purchased from E. I. Nemours Dupont Company (abbreviated as “Dupont” below) of US. The fluorine-free solvent can be selected from alcohol, ketone, nitrile, cyclic ether, non-cyclin ether, and a mixture thereof. The proper fluorine-free solvent comprises methyl alcohol, ethyl alcohol, propyl alcohol, isopropyl alcohol, acetone, methyl ethyl ketone, acetonitrile, tetrahydrofuran and a mixture threof, preferably methyl alcohol, ethyl alcohol or isopropyl alcohol, and most preferably ethyl alcohol. In the invention, the at least one solvent has a normal boiling point of about 50-150° C. and preferably, a normal boiling point of about 60-120° C. The content of the at least one solvent is about 96.0%-99.9% of weight of the total weight of the coating composition.

Wherein the at least one of any catalyst can promote the covalent bonding of the trivalent fluorine-containing silane fragment and the transparent substrate in the front panel of the solar cell module. The at least one of any catalyst contains acid, alkali or water; examples of the acid comprise inorganic acid, alkyl sulfonic acid, halogenated alkyl sulfonic acid, carboxylic acid, halogenated carboxylic acid and a mixture thereof. Examples of the inorganic acid comprise hydrochloric acid, sulfuric acid, nitric acid and a mixture thereof. The examples of the alkali comprise inorganic alkali, substituted and non-substituted trialkylamine, pyridine and derivative thereof and a mixture thereof. Examples of inorganic alkali comprise sodium hydroxide, potassium hydroxide, and a mixture thereof. The content of the at least one of any catalyst is 0-about 2.0% of weight of the total weight of the coating composition.

The coating can be any wet process coating or drying process coating. Examples of the drying process coating comprise chemical vapor deposition and physical vapor deposition. Examples of the wet process coating comprise dipping coating, spraying coating, rotary coating, flow spraying, roller coating, meniscus coating, intaglio coating and the like.

In one embodiment of the invention, the antifouling layer is prepared by the following method: (a) providing a coating composition, which comprises at least one trivalent fluorine-containing silane, at least one solvent and at least one of any catalyst; (b) coating the coating composition to the front side of the transparent substrate; and (c) drying and curing the transparent substrate coated with the coating composition.

Before coating, the trivalent fluorine-containing silane, the at least one solvent and the any at least one catalyst are mixed, so the trivalent fluorine-containing silane is totally dissolved in the at least one solvent to prepare the coating composition.

Before coating, the transparent substrate also needs to be cleaned and/or pretreated by using a technique known in the art. For example, the transparent substrate is firstly washed with alkali such as a water solution of sodium hydroxide or potassium hydroxide, then rinsed with deionized water, then washed with acids such as hydrochloric acid or nitric acid, then rinsed with the deionized water, then rinsed with absolute methanol or ethyl alcohol, and finally dried.

The coating method is preferably wet process coating, more preferably spraying coating, namely, a spray gun is used to coat the coating composition at the front side of the transparent substrate.

After coating, the coated transparent substrate needs to be dried and cured, for example, placed under room temperature for 24 hours, thus obtaining the antifouling layer.

The solar cell module in the invention may further comprise a back plate positioned at the non-light-receiving side of the solar cell layer, and any proper glass or plastic plate can be used as the back plate. The proper materials of the plastic back plate can comprise but are not limited to glass, polycarbonate, crylic acid, polyacrylate, cyclic polyolefin, ethylene norbornene polymer, metallocene-catalyzed polystyrene, polyamide, polyester, flurone-contained polymer and the like, and combination thereof, and in some applications, the fluorine polymer-polyester-fluorine polymer (for example, TPT) is preferable.

In addition, the solar cell module in the invention can further comprise a front packaging layer positioned between the solar cell layer and the front panel and/or a back packaging layer positioned between the solar cell layer and the back panel. Materials for forming the front packaging layer and the back packaging layer comprise, but are not limited to, ethylene/ethylene-vinyl acetate (EVA) copolymer, ionomer, polyvinyl butyral (PVB), polyurethane (PU), polyvinyl chloride (PVC), polyethylene, polyolefin block elastomer, ethylene/methacrylic acid alkyl ester copolymer, ethylene/methacrylic acid copolymer, silicone elastomer, epoxy resin and the like. It should be noticed that the front packaging layer has transparency, allowing sufficient sunlight to reach the solar cell.

The solar cell module disclosed in the text can be further embedded in other function films or plate layers (for example, a dielectric layer or a barrier layer) in the solar cell module. For example, a polyethylene terephthalate film coated with a metal oxide coating, which is disclosed in, for example, the U.S. Pat. Nos. 6,521,825 and 6,818,819 and European Patent EP 1182710, can serve as a transparent multilayer lamination matter or an oxygen and water content barrier layer in the solar cell module.

The solar cell module disclosed in the text can be prepared by any proper process such as a lamination process.

There is no need of further detailed description, and it is believed that those skilled in the art can fully use the invention by the above description. Therefore, it should be understood that following embodiments are only schematic without limiting the disclosure.

### EMBODIMENTS

Abbreviation “E” stands for “embodiment”, abbreviation “CE” stands for “contrast embodiment”, the numbers thereafter stand for the embodiment or contrast embodiment in which the solar cell module is prepared. All embodiments and contrast embodiments can be prepared and tested with similar methods. Unless otherwise stipulated, the percentage is calculated based on weight.

Materials used in embodiment E1 and contrast embodiment CE1:
Solar cell: the 5-inch single crystalline silicon solar cell purchased from JingAo Solar Co., Ltd. in China;
Glass panel: embossed tempered glass with the dimension of 29.8 cm*27.8 cm*0.32 cm purchased from Suzhou Tsinghua Optical Lens Co., Ltd. in China;
Trivalent fluorine-containing silane: C₃F₇O(CF(CF₃)CF₂O)ₙCF(CF₃)CH₂OCH₂CH₂CH₂Si(OCH₃)₃ purchased from Dupont;
Solvent: 2H, 3H decafluoropentane purchased from Dupont;
EVA sheet: Revax™ ethylene/vinyl acetate sheet which is 0.45 mm thick and purchased from WenZhou RuiYang Photovoltaic Material Co., Ltd. in China;
Back plate: TPT back plate purchased from Taiflex Scientific Co., Ltd. in Taiwan;
Aluminum frame: purchased from Jiangyin Lutong Material Trading Co., Ltd. in China.

Preparation method of the solar cell module in the embodiment E1 and contrast embodiment CE1

In the embodiment E1 and contrast embodiment CE1, the solar cell module is prepared according to following steps:

Step 1: Laminating

performing vacuum laminating on following structures: the glass panel/EVA sheet/solar cell part/EVA sheet/back plate at 145° C. for 3 minutes, then pressing for 10 minutes (100 kPa), and finally placing into the aluminum frame to obtain the solar cell module of the contrast embodiment CE1 and the solar cell module to be coated with the antifouling layer of the embodiment E1. Wherein each solar cell part consists of 4 single crystalline silicon cell pieces in 2 rows and 2 columns.

Step 2: preparing the antifouling layer of the embodiment E1

Firstly mixing the trivalent fluorine-containing silane and the solvent for at least 10 minutes according to the weight ratio of 1:99 to prepare a coating composition;

Then performing cleaning and pretreatment on the glass panel of the solar cell module coated with the antifouling layer of the embodiment E1 according to following steps: 1) cleaning the front side of the glass panel with deionized water; 2) smearing the front side of the glass panel with a sodium hydroxide solution of 2.5 mol/L and keeping at a moisturized state for 30 minutes; 3) cleaning the front side of the glass panel with the deionized water; 4), smearing the front side of the glass panel with a hydrochloric acid solution of 0.1 mol/L and keeping at the moisturized state for 30 minutes; 5) cleaning the front side of the glass panel with the deionized water; 6) smearing the front side of the glass panel with methyl alcohol; 7) drying the front side of the glass panel at room temperature.

Finally, spraying a layer of above coating composition at the front side of the glass panel with a manual spray gun (model: Anest Iwata LPH-50) at a speed of 5 cm/s, sequentially spraying along the upper frame from left to right with the spray gun, turning downwards to spray leftward according to a U-shaped line after the spray gun reaches the rightmost part, the pressure of the spray gun is 0.1 MPa, and then placing the coated glass panel for 24 hours at the room temperature to obtain the antifouling layer with the thickness of about 10 nm-20 nm, thus obtaining the solar cell module comprising the antifouling layer of the embodiment E1.

Antifouling test of the solar cell module in the embodiment and contrast embodiment

Outdoor test conditions: the manufactured solar module is placed on a roof for a month without being connected to a power grid (Feb. 21, 2014-Mar. 21, 2014 during which no manual cleaning is performed).

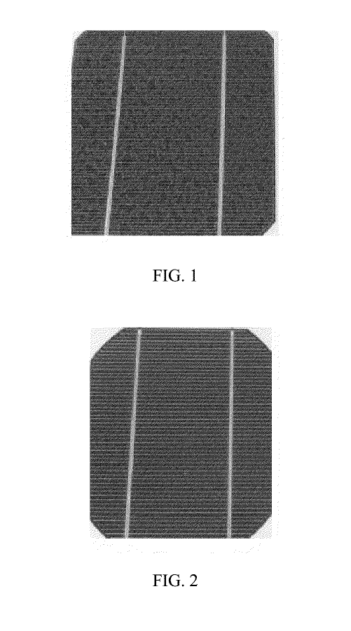

Dust accumulation result: the front side of the solar cell module is shot by a digital camera (model: FinePix HS28EXR), and the dust accumulation condition of the front side of the solar cell module is recorded, as shown in FIG. 1 and FIG. 2.

Power loss of the solar cell module: the initial power P₀ of the solar cell module is measured by a solar cell module measuring system (model: SPI-SUN SIMULATOR™, model: 3500SLP), then the power P is measured again after the solar cell module is placed on the outdoor roof for a month, and the power loss ratio (ΔP) % is calculated according to the following formula:

(ΔP) %=[(P₀−P)/P₀]×100 (1)

P₀, P and (ΔP) % of the solar cell module in the embodiment and contrast embodiment are listed in Table 1.

TABLE 1

| | | | Power loss |
|---|---|---|---|
| Solar cell module | P₀(W) | P(W) | ratio (ΔP)% |
| CE1 | 10.79 | 10.04 | 7.0 |
| E1 | 9.85 | 9.32 | 5.4 |

According to the results of FIG. 1, FIG. 2 and Table 1, the following conclusion is obvious.

By comparing FIG. 1 and FIG. 2, it can be seen that after the antifouling layer-free solar cell module CE1 is placed outdoors for a month, lots of dust is accumulated at the front side of the solar cell module, while after the solar cell module E1 containing the antifouling layer is placed outdoor for a month, the front side of the solar cell module is comparatively cleaner.

By contrasting the power loss ratio of the solar cell modules of CE1 and E1, it can be seen that after the antifouling-layer-free solar cell module CE1 is placed outdoors for a month, the power loss ratio of the solar cell module is 7.0%, while after the solar cell module E1 containing the antifouling layer is placed outdoor for a month, the power loss ratio of the solar cell module is reduced to 5.4%, namely, the antifouling layer can effectively improve the transmittance of the front panel glass of the solar cell module, so the power of the solar cell module is further improved.

1. A solar cell module, comprising: (i) a solar cell layer, including a solar cell part and having a front side and a rear side, and the solar cell part being formed by one or more solar cells, and (ii) a front panel positioned at the front side of the solar cell layer, wherein the front panel is formed by a transparent substrate and an antifouling layer positioned at the front side of the transparent substrate, wherein the antifouling layer comprises at least one trivalent fluorine-containing silane fragment in the following formula: 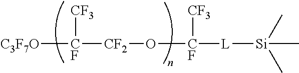
Wherein, n is an integer between 7-40, L is a bivalent organic group selected from —CH₂OCH₂CH₂CH₂— and —C(O)NHCH₂CH₂CH₂—, and the at least one trivalent fluorine-containing silane fragment and the transparent substrate are subject to covalent bonding.

2. The solar cell model according to claim 1, wherein L is —CH₂OCH₂CH₂CH₂—.

3. The solar cell model according to claim 1 or 2, wherein the transparent substrate is glass.

4. The solar cell model according to claim 1 or 2, wherein the antifouling layer is formed by coating a coating composition with the trivalent fluorine-containing silane in the following formula: C₃F₇O(CF(CF₃)CF₂O)ₙCF(CF₃)-L-Si(OR)₃ to the front side of the transparent substrate, wherein n is an integer between 7-40, L is a bivalent organic group selected from —CH₂OCH₂CH₂CH₂— and —C(O)NHCH₂CH₂CH₂—, and R is respectively independently selected from methyl, ethyl, propyl or isopropyl.

5. The solar cell model according to claim 4, wherein the antifouling layer is prepared by a following method: (a) providing a coating composition, which comprises at least one trivalent fluorine-containing silane, at least one solution and at least one of any catalyst; (b) coating the coating composition onto to the front side of the transparent substrate; and (c) drying and curing the transparent substrate coated with the coating composition.

6. The solar cell model according to claim 5, wherein the at least one solvent contains a fluorine-containing solvent with a normal boiling point of 50-150° C.

7. The solar cell model according to claim 6, wherein the at least one solvent is selected from hydrofluorocarbon, hydrofluorocarbon saturated ether, unsaturated fluorocarbon ether and a mixture thereof.

8. The solar cell model according to claim 6, wherein the at least one solvent is saturated hydrofluorocarbon.

9. The solar cell model according to claim 5, wherein the at least one solvent contains a fluorine-free solvent, the fluorine-free solvent is selected from alcohol, ketone, nitrile, cyclic ether, non-cyclin ether, and a mixture thereof, and the normal boiling point of the fluorine-free solvent is 50-150° C.

10. The solar cell model according to claim 9, wherein the at least one solvent is selected from methyl alcohol, ethyl alcohol, propyl alcohol, isopropyl alcohol, acetone, methyl ethyl ketone, acetonitrile, tetrahydrofuran and a mixture thereof.

11. The solar cell model according to claim 2, wherein the transparent substrate is glass.

12. The solar cell model according to claim 2, wherein the antifouling layer is formed by coating a coating composition with the trivalent fluorine-containing silane in the following formula: C₃F₇O(CF(CF₃)CF₂O)ₙCF(CF₃)-L-Si(OR)₃ to the front side of the transparent substrate, wherein n is an integer between 7-40, L is a bivalent organic group selected from —CH₂OCH₂CH₂CH₂— and —C(O)NHCH₂CH₂CH₂—, and R is respectively independently selected from methyl, ethyl, propyl or isopropyl.

13. The solar cell model according to claim 12, wherein the antifouling layer is prepared by a following method: (a) providing a coating composition, which comprises at least one trivalent fluorine-containing silane, at least one solution and at least one of any catalyst; (b) coating the coating composition onto to the front side of the transparent substrate; and (c) drying and curing the transparent substrate coated with the coating composition.
